(19) United States
(12) Patent Application Publication
(10) Pub. No.: US 2024/0201226 A1
(43) Pub. Date: Jun. 20, 2024

(54) A SYSTEM AND A METHOD OF DETERMINING INFORMATION RELATING TO A PERIODIC SIGNAL

(71) Applicants: QDEVIL APS, Copenhagen O (DK); UNIVERSITY OF COPENHAGEN, Copenhagen K. (DK)

(72) Inventors: Joost VAN DER HEIJDEN, Copenhagen O (DK); Ferdinand KUEMMETH, Copenhagen O (DK); Merlin VON SOOSTEN, Copenhagen O (DK); Soren ANDRESEN, Copenhagen O (DK); Anders KUHLE, Copenhagen O (DK); Jonatan KUTCHINSKY, Copenhagen O (DK)

(21) Appl. No.: 18/555,892

(22) PCT Filed: Apr. 8, 2022
(86) PCT No.: PCT/EP2022/059412

§ 371 Date: Oct. 18, 2023

(30) Foreign Application Priority Data
Apr. 19, 2021 (EP) 21169150.6

(51) Int. Cl. G01R 15/14; H03K 5/00; H03K 5/01

(52) U.S. Cl. CPC G01R 15/146; H03K 5/01; H03K 2005/00013; H03K 2005/00286

(57) ABSTRACT

A system for determining information relating to a first periodic signal, the system comprising a sequence of storage elements each configured to store at least one charged particle, where a signal with a constant voltage and a signal with a varying voltage is fed to each storage element. One of the signals with the varying voltage is the first periodic signal. By monitoring the current pumped between the storage elements by the voltages applied to the storage elements, the information relating to the first periodic signal may be generated.

### BACKGROUND

The present invention relates to a system and a method of determining information relating to a periodic signal and in particular to a method according to which the signal is used for generating a current in a sequence of storage elements, where the detection of the current will assist in determining the signal.

In general, and especially in cryogenic systems, signals fed over signal lines or conductors will experience deterioration, so that the signal fed into the signal line at one end will not be identical to the signal output at the other end. However, often, it is the signal at the other end, which is desired known, and not the least when this signal is at cryogenic temperatures for feeding to e.g. a quantum computer processor. It is difficult, however, to determine a signal output from a signal line at cryogenic temperatures. This, then, means that the signals fed to the cryogenic area, such as signal to be fed to a quantum computer core, are not well known, making the quantum computer operation less predictable.

Examples of voltage detection technology may be seen in: “Radio Frequency Reflectometry of Single-Electron Box Arrays for Nanoscale Voltage Sensing Applications”, Zirkle et al, Appl. Sci, 2020, 10(24), 8797 (https://doi.org/10.3390/app10248797), “Using single-electron box arrays for voltage sensing applications”, Filmer et al, Appl. Phys. Lett, 116, 213103 (2020) (https://doi.org/10.1063/5.0005425), and “Time-domain characterization and correction of on-chip distortion of control pulses in a quantum processor”, Rol et al, Appl. Phys. Lett, 116, 054001 (2020) (https://doi.org/10.1063/1.5133894). Double quantum dots may be seen in Petta et. al. Science 309, 2180 (2005).

Other relevant technology may be seen in Chorley S J et al: “Quantized charge pumping through a carbon nanotube double quantum dot”, Applied Physics letters, AIP publishing, PLL, US, vol. 100, No. 14, 2 Apr. 2012, Platonov S et al: “Lissajous rocking ratchet”, Arxiv.org Cornell Univ. Library, 201 Olin Library, Cornel Univ. Ithaca, 13 Mar. 2015 and Mills A R et al: “Shuttling a single charge across a one-dimensional array of silicon quantum dots”, Arxiv.org, Cornell Univ. Library, 201 Olin Library, Cornel Univ. Ithaca, 11 Sep. 2018.

### SUMMARY

The present invention relates to manners which may be used in such set-ups.

In a first aspect, the invention relates to a system for determining information relating to a first periodic signal, the system comprising:
a sequence of storage elements each configured to store at least one charged particle,
a first terminal configured to deliver charged particles to and receive charged particles from a first storage element of the sequence of storage elements, the first storage element configured to receive a first DC signal and a first AC signal comprising the first periodic signal,
a signal source configured to provide a second periodic signal having a period at least substantially equal to an integer times a period of the first periodic signal or the period of the first periodic signal divided by an integer,
a second terminal configured to deliver charged particles to and receive charged particles from a second storage element of the sequence of storage elements, the second storage element being configured to receive the second periodic signal, as a second AC signal, and a second DC signal,
a current sensor configured to sense a current transmitted between or through the at least two storage elements and output a corresponding current signal, and
a processor configured to:
   a) a number of times:
      a. during a plurality of periods of the first AC signal, receive the current signal while keeping the first and second DC signals constant and
      b. determine or obtain information as to the voltages of the first and second DC signals, where the first and/or second DC signals vary/ies from time to time, and
   b) determine the information based on the current signals.

It is noted that the source of the first signal, such as a conductor, cable, signal line or the like, need not be a part of the system. The system may comprise an input for receiving the first periodic signal. All of the system may be monolithic, or the system may be formed by multiple elements or portions, some of which are configured to be at around room temperature and other parts configured to be at cryogenic temperatures.

A sequence of storage elements is provided. A first terminal and a second terminal are provided which are configured to deliver charged particles to and receive charged particles from the first and second storage element, respectively. Often, terminals of this type are called “reservoirs”.

The structure of the storage elements and terminals is known for a different use: a current pump. By varying the voltages of the storage elements in a predetermined manner, a predetermined current of electrons may be pumped through the storage elements. The present use of this structure, however, is rather different.

In this context, a storage element is a structure capable of receiving, holding and emitting/outputting a charged particle, such as an electron, a hole, an ion or more exotic structures (see further below). A storage element may be provided or generated in a number of manners, such as in the form of so-called quantum dots.

The sequence of storage elements allows a charged particle to move sequentially through the storage elements from the first terminal to the second terminal. The sequence of storage elements may comprise only the first and second storage elements, but additional storage elements may be provided if desired.

A current sensor is provided for determining a current flowing between the storage elements in the sequence. In this context, the relevant current is that generated by the voltages. Clearly, currents are seen when storage elements receive charges from reservoirs, for example, or thermally exited currents where charges move back and forth between storage positions. The current of interest often will be that moving from one terminal to the other via the storage positions. In this context, currents created by charges moving back and forth between e.g. the storage positions will cancel out. The current sensor may be provided at any position between the two terminals, such as between the first terminal and the first storage position, between the first and second storage positions or between the second storage position and the second terminal. Often, one terminal or both terminals may be provided at room temperature, so that the current sensor may also be at room temperature. A large number of current sensor solutions exist which are operable at room temperature.

As mentioned, portions of the system may be configured to be provided at cryogenic temperatures, such as the storage elements and optionally also the current sensor and/or signal source generating the second periodic signal, where other portions, such as the processor and often the current sensor, may be provided at higher temperatures, such as at room temperature. The current signal may then be transported to the processor in a manner so that the contents are easily determined after having been conveyed to the controller. Current sensors are typically current to voltage converters provided at room temperature.

The function of the two AC voltages may be seen in a voltage space or plot displaying the first AC voltage along one axis and the second AC voltage along another axis. When the two AC signals have the same (or integer multiple) frequency, a looping or repeating trajectory is seen in the voltage space over one period of the signals. This trajectory may be called a Lissajous curve.

In a system with two storage elements for charged particles, such as particles with quantized energy levels, located between e.g. two equipotential reservoirs, current can only flow through this system in so-called triple points. This happens when for each storage element a quantized energy level lines up with the chemical potentials of the reservoirs. This is often seen as a single point in the voltage space or plot described by the two voltages which may be used for controlling the electrochemical potentials of the two storage elements.

The plot may instead display, along one axis, the sum of the first AC voltage and the first DC voltage, and, along the other axis, the sum of the second AC voltage and the second DC voltage. The loop or trajectory then may be positioned at desired locations in the plot by varying the DC voltages. By moving such a curve around in the voltage space (by controlling the DC voltages) in the vicinity of a triple point, current will be measured when the trajectory goes around (encircles) the triple point. This measurement of pumped current can be used to find the Lissajous curve of the two AC signals, and therefore extract information of one or both of the AC signals.

The current measurement may contain more information than just the positive current, negative current or no current. The absolute value of the current represents information as to a frequency of the signal. When the signal is unknown and this signal phase shifted as a second signal, the absolute value of the current may be used for establishing the frequency of the unknown signal. The direction of the loop (clockwise or counterclockwise) defines the direction or sign of the current.

Furthermore, the trajectory may loop multiple times around a ‘triple point’, thereby possibly generating currents of ±2ef, ±3ef, . . . ±n ef, which is information required to establish the trajectory. Thus, the current may represent an integer times the frequency.

In this context, the current will depend also on the frequency of the signal. Thus, in order for the current to be sufficiently large for it to be determined, the frequency of the signal may be desired sufficiently high, such as at least 10 kHz. If a higher charge is transported per period, signals having a lower frequency may be determined.

The current transported between the first and second storage positions will be defined by the voltages or potentials of the first and second storage positions as well as any barrier which the charged particle has to pass in order to travel between the first and second storage positions.

In this context, it is desired that the storage positions have a low self-capacitance, such that there is a large energy difference (and therefore voltage difference) between the charging events of additional charged particles to the storage position. It may be preferred that only a single charged particle at a time moves between the terminals and storage positions in a range of 10-100 mV. This voltage range depends on the strength of the coupling between the storage position and the method of applying the DC and AC signals and could be further extended by design. Furthermore, the same method can be used when a small number of charged particles are allowed to move between the terminals and storage positions, which would also allow an extension of the voltage range. This voltage or barrier may be determined by selection of the material of the storage position, such as the material storing the charged particle and/or material surrounding this storing material. Alternatively, or additionally, electric/magnetic fields may be provided for defining this barrier.

Usually, the energy required to move the charged particles between the storage positions or between a terminal and storage position is very small. At a certain combination of DC voltages, all energy levels are aligned and charged particles can move freely in either direction. The voltage only has to change more than the thermal energy (or tunnel-rate energy, if this is larger), to allow only one direction for the charged particles. This voltage scale is typically in the μV range.

The first storage element is configured to receive at least two signals, comprising the first DC signal and the first periodic signal as an AC signal.

The second storage element is configured to receive at least two signals, comprising the second DC signal and the second periodic signal as an AC signal.

The two or more signals for a storage element preferably are simply added, so that the voltages of the signals are added. The resulting signal may then be fed to the pertaining storage element.

The addition of the DC and AC signals can be achieved with the use of a bias tee.

The signal source may generate the second AC signal in a number of manners. In some situations, the second AC signal is based on the first AC signal. In other situations, the second AC signal is completely independent on the first AC signal—apart from the periods of the first and second AC signals corresponding as described.

In this context, the AC signals and DC signals are signals with varying and constant voltages, respectively.

The DC signal preferably is a signal which does not vary in voltage. However, as will become clear further below, it is preferred that the DC signals in fact are varied, but either very slowly or in steps, so that during a determination of the current, the two DC signals are kept constant, while the AC signals are allowed to vary. After that, new values may be selected for one of or both DC signals, where after the current is again determined. A voltage may be said to be constant, if it varies no more than 1%, such as no more than 0.5%, such as no more than 0.1%, such as no more than 0.05%, such as no more than 0.01%, such as no more than 0.005% within a time period of one of the AC signals, such as within at least 10 periods of one of the AC signals, such as within at least 100 periods of one of the AC signals, such as within at least 10,000 periods of one of the AC signals, such as within at least 1,000,000 periods of one of the AC signals, such as within at least 100,000,000 periods of one of the AC signals.

The current is determined during periods of the AC signal in which the DC signals are kept constant or at least substantially constant. Then, the DC signals may be allowed to change when the current is not determined or when any determined current is not used in the determination of the information.

The current is determined during a plurality of periods of the first AC signal or the first periodic signal, such as during at least 10 periods, such as during at least 100, such as during at least 10,000 periods, such as during at least 100,000 periods, such as during at least 1,000,000 periods, such as during at least 100,000,000 periods of the first AC signal or the first periodic signal.

Often, the first periodic signal has a voltage swing (highest voltage subtracted the lowest voltage) of between 1 and 500 mv, such as between 3 and 50 mv, such as between 5 and 25 mv. When the storage elements are quantum dots, the spacing between adjacent triple points often are on the order of 10 mv, and it may be desired that the voltage swing encompasses only one quantum triple point even though this is not a requirement.

In addition, it may be desired that two DC voltages used, for the first and/or the second DC signals, in adjacent current signal determinations, have a difference lower than the voltage swing of the first periodic signal. It may be desired that the difference between two DC voltages of the first DC signal and/or the second DC signal used in adjacent measurements is less than 90%, such as less than 75%, such as less than 50%, such as less than 25%, such as less than 20%, such as less than 15%, such as less than 10%, such as less than 5% of the voltage swing of the first periodic signal. Also, it may be desired that two DC voltages used, for the first and/or the second DC signals, in adjacent current signal determinations, have a difference lower than a voltage difference between two adjacent triple points. It may be desired that the difference between two DC voltages of the first DC signal and/or the second DC signal used in adjacent measurements is less than 90%, such as less than 75%, such as less than 50%, such as less than 25%, such as less than 20%, such as less than 15%, such as less than 10%, such as less than 5% of the voltage difference between the two adjacent triple points. Naturally, one or both of these two triple points may be positioned within the 2D curve when at least one of the first and second DC signals has one of the two DC voltages.

The current signal corresponds to the current so that the current may be determined from the current sensor. Preferably, the current signal represents both the current as well as a direction of the current, i.e. whether the charge moves from the first storage element to the second storage element or in the opposite direction.

It is noted that when the difference in potential or voltage between the first and second storage elements is sufficiently high, charged particles may be transported between the first and second storage elements, causing the current. As the first and second AC signals are periodic and have the same periods or periods differing by an integer, the potentials of the first and second storage elements will vary in a periodic manner which may create a repeated transfer of charged particles and thus the current. This integer may be 1, 2, 3, 4, 5, 6, 7, 8, 9, 10 or more. Preferably, the signals have the same period, as this makes the determination simpler. Clearly, a non-integer difference will generate a varying Lissajous curve. The current may still be determined in the portions of the Lissajous curve corresponding to a integer difference. For example, if a difference of 1.5 was used, the first period of the higher frequency signal will generate a first Lissajous curve shape. Then next period a second shape and a third period a third shape. Then, the fourth period will generate the first shape again. Thus, if a non-integer difference is used but a repetitive sequence of curve shapes is generated, a suitably selected curve within such period may be selected.

If the frequency of the signal is not known, it may, as indicated above, be determined by the current, as the current will be (±1ef, ±2ef, ±3ef, etc.) depending on whether the closed curve loops a triple point and whether it does so once, twice or more. Thus, from the current, the frequency may be determined.

Varying the voltages of the DC signals, the Lissajous curve may be shifted to a position where a triple point of the representation is provided inside the closed curve or a loop thereof. This situation will create the current, as the variation of the voltages of the storage elements will drive or pump a current. If no triple point is inside the loop or closed curve, no current may be seen.

The voltages of the DC signals may then be used for moving the Lissajous curve in relation to a triple point. The relative position of the triple point and the closed curve may then be varied in order to determine the shape of the closed curve. Thus, the processor may be configured to base the determination also on the voltages of the DC signals, such as for each time or point in time.

As it may be determined on which side of the closed curve the triple point is (inside or outside), the closed curve may be determined or tracked in a number of manners.

The processor may be provided in any desired manner. Any type of hardware and topology may be used, such as a controller, processor, ASIC, FPGA, DSP, hardwired or software controllable or a combination thereof. The processor may be monolithic, or the operations thereof may be divided into different elements or pieces of hardware which are configured to communicate with each other. Part of the processing may be performed in the cloud if desired.

The processor receives the current signal and determines the information relating to the first periodic signal. This information may be the actual first signal or its shape, such as the voltage over time of the signal, or a representation, such as a mathematical representation, thereof. A mathematical representation could be an equation describing the voltage over time. Alternatively, the information may be a frequency of the signal or an error signal describing a degree of similarity between the actual signal is from a desired signal.

The processor may derive information relating to a 2-D representation or curve relating to, on one axis the voltage over time of the first AC signal or the first periodic signal and, on the other axis, the voltage over time of the second AC signal. From this and knowledge of the second AC signal or its relation to the first AC signal or the first periodic signal, the voltage over time of the first signal or the first periodic signal may be derived.

The processor operates to obtain the current signal a number of times. Between two “times”, which would normally be two different points in time, one or both voltages of the DC signals are altered, so that the current signal is determined for a number of different pairs of (voltage of first DC signal, voltage of second DC signal).

The controller may itself output the first and second DC signals, or it may be configured to control one or more signal generators configured to output the first and second DC signals. Naturally, in an alternative embodiment, the controller does not control the generation of the first and/or second DC signals but determines the voltages thereof and uses this in the determination of the information. The voltages of the first and second DC signals may be varied in a predetermined manner, so that the controller, knowing how these signals vary over time, merely needs obtain the current signal in order to be able to determine the information relating to the first AC signal.

In a preferred embodiment, the storage elements are quantum dots. Quantum dots are easily manufactured and are well known. Charges in quantum dots may be confined by material boundaries and/or by electric fields arising from gate electrodes, for example. One way of forming quantum dots is by material boundaries only, such as by providing a hemisphere or volume of a first semiconductor material enclosed by a second and different semiconductor material or isolator material. Alternatively, a storage element or dot could be formed by a metallic material enclosed by a semiconductor or insulator material. Another common way is using a combination of material boundaries and gate voltages, where a thin layer of conductive material may be created by layering different semiconductor/isolating materials to confine the charge in one dimension and where gate electrodes may be provided for confining the charge in the other two dimensions.

Other types of storage elements are described further below.

Preferably, the charged particles are electrons—or holes. This is the simplest embodiment, and electrons are by far the most used particle for generating an electrical current. Clearly, any type of charged particle or ion may be used.

In general, the processor preferably comprises information relating to the second AC signal and uses this information in the determination of the information relating to the first AC signal. Different situations exist and different information may be required or desired from the second AC signal.

As mentioned, the second AC signal may in principle be any signal, as long as it follows or complies with the periodicity by an integer factor. The second signal may be independent of the first signal. The information determined from the current and the DC values may then need further analysis in order to arrive at the desired information relating to the first AC signal, but the amount of further analysis depends heavily on the second signal selected.

In one situation, the second signal is a signal with a period having a single monotonic upward portion from a minimum to a maximum and a single monotonic downward portion from the maximum to the minimum. Signals of this type may be saw-tooth shaped, triangular, sine shaped, square shaped or the like.

From a saw-tooth shaped signal, the signal shape of the first AC signal may be directly obtained from the voltages of the DC signals and the currents detected. The voltages may be interpreted as coordinates in a coordinate system with the first AC signal along one axis and the second AC signal along the other axis. In this coordinate system, a closed curve may be provided, formed by the first and second AC signals in the coordinate system. The closed curve will have a direction in that the time evolution of the first and second signals will define coordinates moving along the closed curve in a direction defined thereby. This closed curve may be determined based on the knowledge that, for each pair of voltages, a current will indicate that that particular point in the coordinate system is within a loop of the closed curve. The direction of the current will describe the direction of the closed curve/loop around that point in the coordinate system. Thus, it may be determined when the curve folds over itself and crosses itself, as two adjacent loops will then have oppositely directed currents. Then, the closed curve may be determined in a number of manners. In one manner, the closed curve is detected by simply scanning the voltages of the DC signals to determine the current in e.g. an array of points in the coordinate system. The distance between the points may be selected as desired, such as equidistantly, and it may be desired to provide a lower distance at positions where the closed curve has been determined (change from no current to current, for example). In other situations, the position of the closed curve may be determined by a change in the current, when e.g. the voltage of the first DC signal is varied, and the closed curve may be tracked around its periphery by altering the voltages of the DC signals so as to move along the track. Then, portions in the coordinate system away from the actual closed curve position may not be desired visited.

Having then determined this closed curve, the deriving of the first AC signal may depend on how the closed curve was derived.

For a saw tooth shaped second AC signal, the first AC signal may be determined directly from the closed curve, as the second AC signal will merely increase monotonically. The first AC signal may then be directly read-out along one of the axes of the coordinate system.

For a sine-shaped second AC signal, the first AC signal may be derived from a simple deconvolution of the closed curve.

Especially sine-shaped signals are advantageous, as these comprise only a single frequency component. In most systems, the deterioration of the signal typically is seen as different attenuations at different frequencies, so that the signal fed into a signal line often does not look like that output therefrom. Thus, if the second signal comprised only a single frequency component, such as when it is a sine-shaped signal, only attenuation is seen. The maximum and minimum of the sine wave may simply be determined from maximum and minimum points on the closed curve.

Thus, the second AC signal preferably is a sine-shaped signal, as this may be generated remotely from the storage elements, such as at room temperature where the storage elements are at cryogenic temperatures, while the frequency and the phase of the signal may be well known at the storage elements.

In another embodiment, the signal source is configured to output, as the second periodic signal, the first periodic signal delayed or phase shifted by a predetermined portion. Then, the processor may be configured to determine the information based also on the delay or phase shift. If this delay or phase shift is provided close to the storage elements, such as at cryogenic temperatures, this has the advantage that the second and first signals are derived from the same signal so that there is no unknown independent alteration of the second signal, as could be the situation if the two signals were independent or individually fed through long signal lines or cables. Alternatively, the phase shift or delay may be provided at room temperature. In this situation, the two signals are transmitted through two different transmission lines and therefore get different distortion. Depending on the degree of distortion, this could amount to using two unknown signals, with the same period. Below, signal types are described which are quite suitable for transport over long signal lines and methods of deriving the information even if two unknown signals are used.

Providing the second signal with no delay or phase shift relative to the first signal generates, in the above coordinate system, a curve which is a straight line, which is more difficult to convert into the first signal.

If a delay or phase shift is provided, the resulting curve may open up so that positions in the coordinate system exist which are within the closed curve and which then generate a current.

It may be desired to be able to vary the delay or phase shift, as some delays/phase shifts will generate a more easily detectable closed curve than others, and as different first AC signals will have different shapes, it may not be possible to determine a single delay/phase shift which suits all first AC signals.

It may be preferred that the signal source comprises a plurality of individual delay circuits, such as delay lines, and a switching structure for selecting any one of the delay circuits. This rather simple structure may be provided at the storage elements and thus at cryogenic temperatures, which has the advantage that the second AC signal then may be much closer to the first AC signal, apart from the delay/phase shift, than if the second AC signal was generated at room temperature and then transmitted separately to the storage elements. Operating the switches, a copy of the first AC signal may then be fed into one of the delay circuits or delay lines to obtain the desired delay. Naturally, the signal may be sequentially fed through multiple delay circuits or delay lines in order to obtain a larger delay/phase shift.

Clearly, the signal source may be controllable by the controller to select one of a plurality of predetermined delays or phase shifts, the controller could then be configured to:
for a plurality of different delays or phase shifts:
control the delay element to delay the periodic signal by the pertaining delay or phase shift, and
perform steps a. and b,
where step b) comprises determining the information from the received current signals and the delays/phase shifts.

Then, different closed curves are derived from different delays or phase shifts. It may not be possible to determine the first AC signal only based on a closed curve obtained from a single delay or phase shift. This may be due to the closed curve being so compact, using a particular delay/phase shift, that it is difficult to identify pairs of voltages of the DC signals which are provided within loops of the closed curve, for example. Also, multiple closed curves may be required, as a single closed curve may not comprise sufficient information to allow the deriving of the first AC signal. Providing a number, such as 2, 3, 4, 5, 6, 7, 8, 9, 10 or more different delays or phase shifts, closed curves will be seen for some delays/phase shifts which are more easily determined.

Clearly, the above methods may be combined so that the processor may be configured to control the signal source to output a selected second periodic signal of a plurality of second periodic signals, and wherein the processor is configured to:
perform step a) for each of a number of different second periodic signals and
perform step b) on the basis of the current signals received and the second periodic signals used for each step a).

As described, different second signals have different advantages, and combining these brings about a combination of such advantages.

It is noted that the present system may be operated in an alternative manner. The processor may comprise knowledge of the desired shape of the first AC signal and of the second AC signal. From this, an expected closed curve may be derived. Then, from the voltages of the DC signals and the currents determined, an overlap of the actual closed curve, which needs not be determined, and the desired closed curve may be determined. If the current is not seen at coordinates where it is expected and if a current is seen at coordinates where it is not expected, a poor overlap may be seen, and the signal fed into the signal line outputting, at the other end, the first AC signal may then be varied until a desired or minimum overlap is seen. Then, the first AC signal may be assumed to be as expected.

Thus, by selecting the voltages of the DC signals, the operation of the AC signals on the storage elements will drive a current, which is determined. By selecting different DC voltages, different currents may be pumped or driven and from this the closed curve may be determined from which the signal or signals generating the AC signals may be determined.

A second aspect of the invention relates to a method of determining information relating to a first periodic signal, the method comprising the steps of:
providing a second periodic signal having a period at least substantially equal to an integer times a period of the first signal or the period of the first signal divided by an integer,
a plurality of times:
feeding the first periodic signal, as a first AC signal, to a first storage element in a sequence of storage elements,
feeding a first DC signal to the first storage element,
feeding the second periodic signal, as a second AC signal, to a second storage element in the sequence of storage elements,
feeding a second DC signal to the second storage element,
varying the first and/or second DC signal varying from time to time,
detecting any current transmitted between the first storage element and the second storage element,
determining the information from the determined currents.

Naturally, all embodiments, situations and other considerations made in relation to the first aspect of the invention are equally relevant in relation to this aspect of the invention.

In this connection, the same relation is desired between the periods of the first and second periodic signals.

Again, the sequence of storage elements is seen, and again, the first AC signal and the first DC signal are fed to the first storage element where the second storage element receives the second AC signal and the second DC signal.

The voltages of the first and/or second DC signals are varied from time to time or from point in time to point in time. Points in time, such as equidistantly, may be defined at which the current is sensed and between which the voltages of the DC signals are altered, so that the voltages of the DC signals are at least substantially constant when the current is sensed. Then, the current is defined by the variation in the AC signals and not in the DC signals.

As mentioned, the current may be zero, such as if the Lissajous curve does not have a triple point inside it.

Again, the detection of the current may comprise a size of the current and/or a direction of the current.

Again, the information desired may be determined from the currents determined at the points in time.

The step of feeding the first periodic signal may comprise feeding the signal from a signal generator provided at one temperature, such as a temperature above 100K, to the first storage element, which is provided at a temperature below 100K.

Also, the step of providing the second periodic signal may comprise generating the second periodic signal in a signal generator provided at one temperature, such as a temperature above 100K, and feeding the signal to the second storage element, which is provided at a temperature below 100K. Alternatively, the step of providing the second periodic signal may comprise generating the second periodic signal in a signal generator provided at a temperature below 100K, such as below 1K, and feeding this signal to the second storage element, which is also provided at a temperature below 100K, such as below 1K.

As described above, the second AC signal may be independent, apart from its period, of the first AC signal, and may be e.g. a sine-shaped or saw tooth-shaped signal.

On the other hand, the second periodic signal may correspond to the first periodic signal being delayed or phase shifted by a predetermined portion. In this situation, the step of determining the information preferably comprises basing the determination also on the delay or phase shift.

In this situation, and especially when the first and second signals are transported to the storage elements via separate signal lines, such as from room temperature to cryogenic temperatures, a delay or phase shift may be determined at which at least substantially no current is generated, such as any or a number of voltages of the DC signals. In this situation, the curve it not a closed curve but a line. Then, the triple point cannot be encircled by the curve, so no current is generated. When the curve is a line, the delay or phase shift identified will describe a relative delay or phase shift between the signal lines. Then, this delay or phase shift may be permanently or subsequently added to one of the signals in order for the two signals to be synchronized at the storage elements.

Generating the second AC signal may then, as described above, be obtained by feeding the first signal into a circuit comprising a plurality of individual delay circuits, and wherein one of the delay circuits is selected for delaying and/or phase shifting the first periodic signal to generate the second periodic signal. Then, the step of determining the information may comprise sequentially selecting a plurality of delays and basing the determination on the currents detected and the delays. In this manner, different information is obtainable from each phase shift or delay, and this may enable the determination of the desired information.

In one embodiment:
the step of providing the second periodic signal comprises sequentially selecting one of a plurality of periodic signals,
the step of detecting the current is performed for each of the second periodic signals, and
the step of deriving the information comprises deriving the information based on the periodic signals selected and the pertaining currents.

In general, when the first and second DC signals do not vary over time, the AC signals may drive a current through the sequence of storage elements. This will depend on whether the Lissajous curve surrounds a triple point of the two storage elements. The relative position of the triple point and the Lissajous curve will be defined by the voltages of the two DC signals. Thus, based on the two voltages and the current, information may be determined relating to the Lissajous curve and thus of the first AC signal, especially when the second AC signal is known or its relation to the first AC signal is known. Determining the current at a number of different pairs of (voltage of first DC signal, voltage of second DC signal) will provide information as to whether a loop of the Lissajous curve is present in the coordinates defined by the voltage pairs. Thus, more information may be derived.

In some embodiments, the Lissajous curve is determined to derive the information therefrom. Different methods are described for this determination, such as the determination of the current for a number of voltage pairs representing multiple positions, such as equidistant positions describing an array, in the coordinate system. Another manner would be to track the closed curve along its extent in the coordinate system.

From this closed curve, the first AC signal may be determined. A single closed curve may suffice, such as if the second AC signal is a sine-shaped signal or a saw tooth shaped signal. In other embodiments, multiple second AC signals may be desired, such as if the second AC signal is a delayed or phase shifted version of the first AC signal.

Determining the first AC signal from the closed curve may be achieved in a number of manners, depending on the second AC signal. In some situations, the first AC signal may be read-out by simply following the value on one of the coordinate axes, as the closed curve is progressed over time. In other situations, the closed curve requires a deconvolution in order to arrive at that stage. In yet other embodiments, a more elaborate method is used.

It may not be required to determine the complete closed curve. In some embodiments, a signal may be expected at a terminal. Then, the corresponding closed curve may be calculated and compared to an actual closed curve. It is noted that from the current generated by a single pair of voltages of the DC signals, information is obtained relating to whether a triple point is within a loop of the Lissajous curve. Thus, an overlap between the actual and the expected closed curve may be estimated using a low number of sets of voltages of the DC signals. From that information, parameters of the first AC signal may be altered and a new determination made, until a suitable or acceptable overlap is seen, where after the first AC signal is assumed to be that desired.

### BRIEF DESCRIPTION OF THE DRAWINGS

In the following, preferred embodiments will be described with reference to the drawing, wherein:

FIG. 1 illustrates a double dot set-up,

FIG. 2 illustrates a Lissajous trajectory of the set-up of FIG. 1,

FIG. 3 illustrates an embodiment of a sensor according to the invention,

FIG. 4 illustrates translation of the closed curve in the diagram,

FIG. 5 illustrates a first manner of determining a closed curve,

FIG. 6 illustrates curve tracking,

FIG. 7 illustrates determining an extreme value,

FIG. 8 illustrates a first closed curve for a first signal shape at one delay,

FIG. 9 illustrates a second closed curve for a second signal at two different delays,

FIG. 10 illustrates a signal generator configured to delay a signal and

FIG. 11 illustrates a first signal and a second signal being the first signal delayed.

### DETAILED DESCRIPTION OF VARIOUS EMBODIMENTS

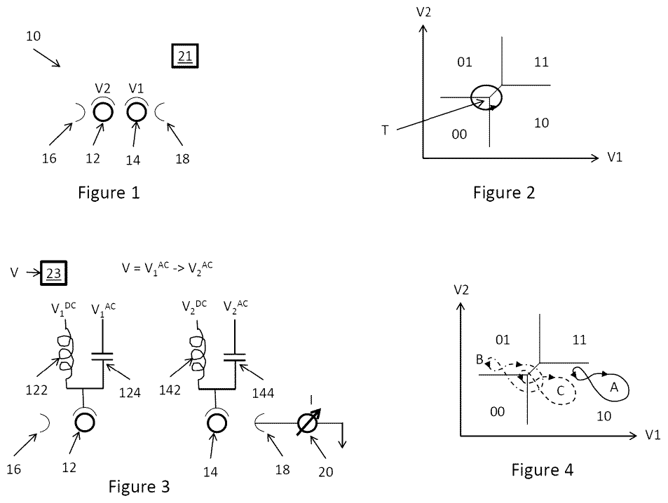

FIG. 1 illustrates a double dot set-up 10 comprising two so-called dots or quantum dots 12 and 14 each connected to an electrode providing a potential to the dot—as well as two electrodes or reservoirs 16 and 18. The dot 12 is kept on a variable potential or voltage V2 and the dot 14 is kept at a variable potential or voltage V1.

By defining the relative potentials of the electrodes 16/18, which preferably is the same potential to allow current in both directions, as well as V1 and V2, electrons may be moved e.g. from the electrode 16 to the dot 12 by keeping the potential V2 lower than that of the electrode 16. Electrons may be moved further from the dot 12 to the dot 14 and finally to the electrode 18. Thus, a current is generated.

Electronics 21 may be provided for defining and/or controlling the voltages/potentials of the dots 12/14 and/or the electrodes 16/18.

FIG. 2 illustrates a charge stability diagram illustrating the gate voltages V1 and V2 at which the individual dots 12 and 14 comprise either no electrons or one electron. A circle-shaped arrow illustrates that if the voltages V1 and V2 are driven as illustrated, using sine-shaped signals, electrons will be transported from the electrode 16 to the dot 12 to the dot 14 and further to the electrode 18, as the state (00), where no dot has an electron, is replaced by the state (10) where the dot 12 has received an electron from the electrode 16, to the state (01) where this electron has been passed to the dot 14, and finally back to the (00) state when the electron has left the dot to the electrode 18. Thus, the closed curve encompasses the triple point T. Thus, by driving the voltages V1 and V2, a current is generated. The current comprises one or a few charges per period of the signal.

The variation over time of the voltages V1 and V2 define the closed curve in FIG. 2 and thus the current generated.

This set-up may be used in a reversed manner, as seen in FIG. 3, to determine information relating to an unknown, periodic signal.

The unknown, periodic signal, V, is fed to the node 12 as V₁ and also fed, but phase or time-shifted in circuit 23, which could form part of the electronics 23, to the node 14 as V₂. Clearly, this feeding of the signals will define a closed curve in the charge stability diagram of FIG. 2.

A current transported through the dots is determined by a current sensor 20.

This closed curve is defined by the two signals, V₁ and V₂ and thus the original signal V and the delay or phase shift. This closed curve may be quite complex and may in principle be situated anywhere in the diagram. In FIG. 4, an example of a resulting closed curve, A, is illustrated.

Clearly, when the triple point T—or in principle any triple point—is positioned inside the closed curve, a current will be transported as described above. The closed curve describes also a direction around the triple point. This direction can be interpreted into a direction of the current flowing between the dots 12 and 14.

Then, by adding DC signals to V₁ and V₂, the position of the closed curve may be shifted in the diagram. In FIG. 3, the AC voltages are fed to the dot via a capacitor 124/144 so that any DC signals are blocked. The DC signals may be fed via inductances 122/142 so that AC contributions are filtered.

In FIG. 4, the closed curve A does not cover a triple point, so no current is transported, but by translating it into closed curves B or C, by adapting the DC signals, it may be brought to a position driving a current. It is seen that when translating closed curve A to the position of the closed curve B, the triple point is now positioned in the large loop of the closed curve B. This loop has a direction opposite to that seen in FIG. 2. Thus, a current is seen from the electrode 18 to the electrode 16.

On the other hand, when the closed curve A is translated to the position of closed curve C, the triple point is inside the small loop, which has the direction as that of FIG. 2, so that a current in the same direction is seen.

From the output of the current sensor 20, it may be determined whether the triple point is in a loop and what direction the loop has around the triple point. Also, from the current, it may be determined whether the closed curve loops the triple point one or multiple times.

Naturally, the current sensed need not merely be either current or not. If the closed curve covers multiple triple points, such as the two triple points illustrated in FIG. 2, the current may be higher or lower, depending on which triple points are enclosed by which parts of the closed curve. Two “oppositely directed” triple points within the same loop will neutralize the current, so that no current is seen. Two triple points acting to generate a current in the same direction will increase the current to twice the value. The net currents of triple points enclosed by a loop of the curve add up or subtract and contribute to the total net current a when multiple electrons may be shifted between the nodes and the electrodes.

Now, varying the two DC signals, this position of the closed curve in the plot may be shifted, so that information may be derived from multiple positions in the closed curve.

A number of manners now exist of determining information from the closed curve.

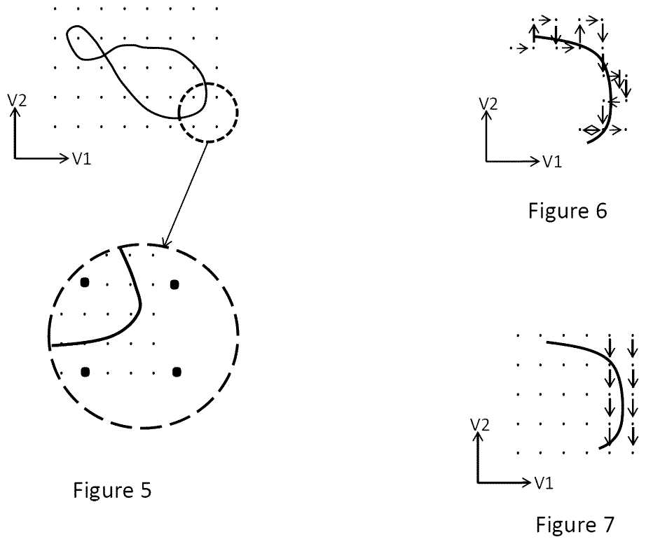

In one manner, the voltages of the DC signals are varied in steps, so that the closed curve is detected at points in a coordinate system in which the closed curve is positioned. In an alternative embodiment, the DC signals may be varied slowly or in steps compared to the period of the signal to be determined. In FIG. 5, points illustrate predetermined V1 and V2 values which may be provided as DC values. A point in the curve of FIG. 5 may be provided at a position of a triple point, if the corresponding DC voltages are fed to the storage elements. For some DC values, the closed curve will be positioned so that the triple point (not illustrated) will be within the loops so that a current is detected. Also, the direction of the loop of the closed curve is determined from the current.

The result may be a determination of the closed curve by pairs (V1,V2) of DC signals or coordinates at which the closed curve is seen (a current is measured) or not seen (no current is measured).

Naturally, a more coarse pattern of (V1,V2) values may be used initially in order to determine an approximate position of the closed curve, where after the relevant portions of the coordinate system or diagram may be searched using smaller increments of the DC signals. In FIG. 5, a portion of the closed curve is seen with the original (fat) (V1,V2) points as well as a more fine pattern is used for performing a more precise position determination of the closed curve.

Another manner may be to use a closed curve tracking method as seen in FIG. 6 where a transition from inside the closed curve (current is detected) to outside of the closed curve (no current is detected) will cause a change in direction of the searching. The transition is seen in a change in the current sensor. Thus, if the closed curve is tracked as illustrated at the top from left towards right, increasing V1 one step per time and adapting V2 to the closed curve, so that if a transition was last identified by increasing V2, a decrease is made in V2. If no transition is seen by a decrease in V2, V1 may be maintained and V2 further decreased. Different strategies exist of tracking the closed curve.

In FIG. 7, a simpler manner of determining the closed curve is seen where one voltage is shifted while the other is constant, until the first voltage has been shifted from one extreme value to another, then the second voltage is shifted and the method repeated.

Also these methods may result in e.g. pairs of (V1,V2) coordinates between which the closed curve is provided. Again, this may be performed using firstly a more coarse pattern of (V1,V2) values where after the relevant portions may be re-analyzed using a finer pattern of DC values.

Combinations of such strategies may be employed in which one strategy, such as that of any of FIGS. 5-7, may be used with a rather coarse resolution, where after another strategy may be used with a higher resolution but now only in the vicinity of the positions of the closed curve as identified.

This will then result in a determination of the closed curve or its shape.

It is recapitulated that this shape will depend on the actual periodic voltage V and the phase shift.

A number of manners exist of determining the information relating to the first signal. As described above, the information may be a period of the signal. This may be obtained from a simple measurement from the current pump.

The information may relate to the closed curve or a signal shape which may be derived from the shape of the closed curve. Different manners exist of arriving at the shape of the closed curve. The deriving of the signal shape from the closed curve may also take place in a number of manners.

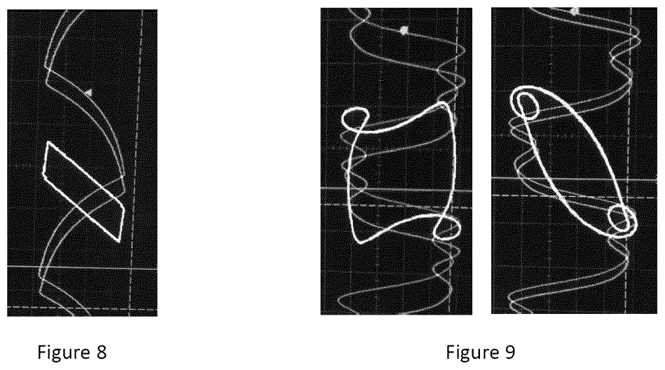

In one situation, an initial point is determined, such as at an extreme value (X or Y value) may be determined. In the situation where different delays are used, for each delay, the point of intersection of the curve at that value (X or Y value) is determined. Then, from the other coordinate (Y or X value) of that point, the shape of the signal may be derived. In fact, even if there is not a single extreme value, the initial point may be at e.g. an X value which the curve passes twice. In that situation, if the curve direction (the curve has a direction defined by the evolution over time of the two signals) in one point is toward lower Y values and the other toward higher Y values, one of these points is selected. For other delays and the same X value, if multiple points on the curve has that X value, the point is determined which has a direction toward higher or lower Y values as that of the initial point. Referring to FIG. 8, the initial point may be either of the corners as they describe the maximum or minimum X or Y values. Alternatively, a Y value may be selected between the two extremes. For that Y value, two points exist on the curve, one going toward higher X values and one going in the direction of lower X values. Either point may be used, and for any other delay, the curve point(s) at that Y value may be determined. The X values determined for the individual delays may be combined into the signal shape, where the delay describes a point in time along the signal and the X value describes the signal value.

As mentioned, it is not required to determine the waveform in the time-domain. In one manner, it is possible to compare the first and second signals. From the above it is clear that if the same signal is used twice (zero phase shift) the closed curve will be a line. If, for example, the same signal is forwarded, as the first and second signals, in two different transmission lines, information may be derived relating to the phase difference between these two lines. By varying a time delay between the two signals, a delay may be determined which results in the closed curve being a line (and therefore resulting in no current being generated), any phase shift or delay created by the lines may be determined. Then, the two signals may be synchronized at the storage positions. The ability to synchronise signals going through two unknown transmission lines is a highly preferred result.

In FIG. 11 a first signal V1 and a delayed version, V2, are illustrated. Clearly, the resulting closed curve may be rather complex, so situations exist where a more simple V2 signal could be advantageous. In one example, a sine-shaped signal is used as V2. This has the advantage that even if the signal is generated far from the quantum dots, the signal deterioration of a single frequency component is normally merely an attenuation so that the phase and frequency are still know even after transmission over a long transmission line. When the second signal is a sine-shaped signal, the first signal V1 may be determined merely from a deconvolution of the closed curve shape. As the known sine signal describes how the trajectory is followed in time on one axis of the closed curve, the measurement of this closed curve can be directly translated in a measurement of how the other signal on the other axis changes in time, using the known information about the sine wave.

If, on the other hand, the second signal has a saw tooth-shaped shape, the frequency contents are more complex, but the first signal may then be directly obtained from the closed curve. As the sawtooth signal ensures the trajectory moves monotonically in time on one axis, one period of the unknown signal will appear as if read-out in time space on the other axis. A closed curve is generated from the point where the sawtooth jumps from its maximum to its minimum value, thereby jumping from the end of that axis to the beginning of that axis, forming a line crossing the waveform of the unknown signal.

Performing the above method for different phase shifts allows the determination of the actual voltage V for the following reasons:

As mentioned, the storage elements may form two or more local minima in energy in a 1-, 2- or 3-dimensional space, where a charge can be ‘trapped’.

The preferred storage element type is a semiconductor quantum dots, which can be confined either by material boundaries, or by electric fields arising from gate electrodes. One common way to form quantum dots is by material boundaries only, such as by providing a hemisphere or volume of a semiconductor material enclosed by a different semiconductor or isolator. These dots could also be formed by a metallic material, enclosed by a semiconductor or insulator. Another common way is using a combination of material boundaries and gate voltages, such as where a thin layer of conductive material is created by layering different semiconductor/isolating materials and which confines the charge in one dimension while gate electrodes confine the charge in the other two dimensions. Electrodes or electrical/magnetic/optical fields may be used for confining the charge in all 3 dimensions if desired.

Other options would be to use the natural 3D local minima created by atoms or by molecules, such as for example C60.

Furthermore, a superconducting island (‘Cooper-pair box’) can be used. Another possibility to create a local minimum in 3-dimensional space would be to use an ion trap.

The at least three energy barriers between the local minima (storage elements) and the (typically metallic) charge reservoirs and between the two local minima can be created in various ways. The barrier could be a vacuum, an insulating material, for instance an oxide, or a semiconductor. These barriers could be further controlled by electric fields, either generated electrically or optically.

The charged particle that is pumped between the storage elements could take several forms as well. It could be either a particle of single elementary charge, like an electron or a hole. Furthermore, it could also be an ion (see for instance ionic coulomb blockade), or even more exotic types, such as a Cooper pair or a trion.

In the above description, the electrons may be prevented from spontaneously moving between the quantum dots by selecting a distance between the dots and/or a material present between the dots. Alternatively, a (E or B) field may be provided presenting a barrier which the electron must move in order to pass from one dot to the other. In this manner, the potentials of the dots may control the flow of electrons/particles, as the electrons/particles will not usually by themselves travel between the dots.

Thus, the electrons may travel between the dots by tunneling. It may be desired to select or tune the storage locations and any barrier (generated or inherent) to a potential difference between the storage locations. This potential difference may be defined by the signal fed at the low temperature. Alternatively, the selected storage locations and the required potential may pose demands as to the potentials and signals fed to the storage locations.

In the above description, the two dots potentials are tuned by the signal and a delayed and/or phase shifted version of the signal. What is preferred is that the resulting closed curve forms loops which may be determined from the current. Such a closed curve may be obtained using any set of signals. Thus, the signal fed to one dot need not be derived from the signal fed to the other dot. Preferably the two signals are each periodic with the same or very similar periods, and the generation of one signal from the other is very recommendable also for the fact that the closed curve is then generated based on a single signal. However, the closed curve may be generated using two independent signals, even though the above decoupling strategy then will be slightly different.

The determination of the shape of the closed curve may be used for different purposes. In one example, the shape of the closed curve is used for determining the actual signal at the storage locations and/or at a location at which the signal is to be used.

In another example, the shape of the closed curve may be used for describing any discrepancy between a desired signal and the determined, actual signal. From the desired signal, an expected or desired closed curve may be derived. This expected or desired closed curve may then be compared to the actual closed curve determined using the above technology. Based on discrepancies between the two closed curves, parameters of the signal fed to the storage locations may be altered to increase a correspondence between the two closed curves and thus obtain a signal at the storage locations which is or is close to that desired.

Preferably, the closed curve shape is determined based on multiple, different delays or phase shifts, as this makes the determination of the signal easier. However, a single delay or phase shift may suffice in a number of situations, one of which being the above-mentioned comparison of the actual closed curve shape to an expected or desired closed curve shape.

In other situations, a single determination may be made, such as if the second signal is a sawtooth signal or a sine wave.

The phase shift or delay used may be selected in more or less automatic manners. In one situation, the phase shift or delay may be selected to arrive at a closed curve shape which is more easily detected. In FIGS. 8 and 9, closed curves are seen for two different signals. In FIG. 9, two closed curves are seen for the same signal but with two different delays between the first and second signals. It is seen that the closed curve to the right may be seen as more difficult to determine, as closed curve tracking at the areas where parallel closed curve portions are seen is more difficult and requires a higher resolution in the determination of the shape of the closed curve. In the closed curve to the left, the closed curve is more open and does not have parallel portions with small relative distances. It may be desired to select a delay or phase shift providing an open closed curve where, if the closed curve has overlapping portions, the overlapping portions stem from closed curve portions which are at a large angle to each other, preferably perpendicular to each other.

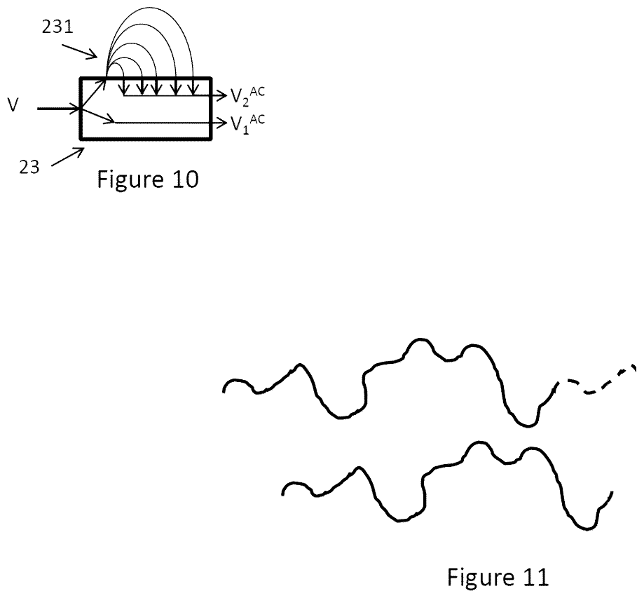

The delay or phase shift may be generated in a number of manners. The delay or phase shift may be generated at room temperature so that the two signals are both fed from room temperature to cryogenic temperatures. It is preferred, however, that the delay is provided at cryogenic temperatures and close to the quantum dots, so that both V₁^{AC} and V₂^{AC} are generated from the same signal. A manner of generating a delay is illustrated in FIG. 10, where the delay circuit 23 comprises a number of delay lines 231 with different delays. In the circuit 23, the input signal V is copied and one copy is output as V₁^{AC} and the other is fed into a selected one of the delay lines 231 and, after the delay, is output as the signal V₂^{AC}. The selection of a delay line may be made using simple switches. An alternative to this would be a phase shifter or a circuit or element with a tunable delay.

It is noted that the two periodic signals fed to the storage positions need not be derived from the same signal. The second signal (not the first signal which is desired determined) may be selected based on the above considerations, so as to obtain an easily determinable closed curve shape. Alternatively, signal shapes may be selected based on which the determination of the unknown signal is simple.

The second signal may have a shape which is completely independent from that of the first signal. For example, if V₂^{AC} is a sine wave or a saw-tooth signal, the resulting closed curve will represent the unknown signal directly or to a degree so that only a slight calculation, such as a deconvolution, is required to arrive at the unknown signal.

Also, it is noted that the signal distortion seen from room temperature to cryogenic temperatures is mainly an unknown attenuation at the individual frequencies, the feeding of a single frequency signal, such as a sine, to cryogenic temperatures will affect the signal strength of the signal but not the phase or frequency. Thus, this signal may rather simply be fed from room temperature to the storage element in question.

1.-16. (canceled)

17. A system for determining information relating to a first periodic signal, the system comprising:
a sequence of storage elements each configured to store at least one charged particle,
a first terminal configured to deliver charged particles to and receive charged particles from a first storage element of the sequence of storage elements, the first storage element configured to receive a first DC signal and a first AC signal comprising the first periodic signal,
a signal source configured to provide a second periodic signal having a period at least substantially equal to an integer time a period of the first periodic signal or the period of the first periodic signal divided by an integer,
a second terminal configured to deliver charged particles to and receive charged particles from a second storage element of the sequence of storage elements, the second storage element being configured to receive the second periodic signal, as a second AC signal, and a second DC signal,
a current sensor configured to sense a current transmitted between the two terminals and output a corresponding current signal, and
a processor configured to:
a) a number of times:
i) during a plurality of periods of the first AC signal, receive the current signal while keeping the first and second DC signals constant and
ii) determine or obtain information as to the voltages of the first and second DC signals, where the first and/or second DC signal vary/ies from time to time, and
b) determine the information based on the current signals.

18. The system according to claim 17, wherein the storage elements are quantum dots.

19. The system according to claim 17, wherein the charged particles are electrons.

20. The system according to claim 17, wherein the signal source is configured to output a sine-shaped or saw tooth-shaped signal.

21. The system according to claim 17, wherein the signal source is configured to output, as the second periodic signal, the first periodic signal delayed or phase shifted by a predetermined portion, and
wherein the processor is configured to determine the information based also on the delay or phase shift.

22. The system according to claim 17, wherein the controller is configured to alter one or both of the first and the second DC signals between two adjacent times of the number of times.

23. The system according to claim 21, wherein the signal source is controllable by the processor to select one of a plurality of predetermined delays or phase shifts, the controller being configured to:
for a plurality of different delays or phase shifts:
control the delay element to delay the periodic signal by the pertaining delay or phase shift, and
perform steps a) and b),
where step b) comprises determining the information from the received current signals and the delays/phase shifts.

24. The system according to claim 17, wherein the processor is configured to control the signal source to output a selected second periodic signal of a plurality of second periodic signals, and wherein the processor is configured to:
perform step a) for each of a number of different second periodic signals and
perform step b) on the basis of the current signals received and the second periodic signals used for each step a).

25. The system according to claim 17, wherein the processor is configured to, in step b), to determine as the information a voltage over time of the first periodic signal.

26. A method of deriving information relating to a first periodic signal, the method comprising the steps of:
providing a second periodic signal having a period at least substantially equal to an integer times a period of the first signal or the period of the first signal divided by an integer,
a plurality of points in time:
feeding the first periodic signal, as a first AC signal, to a first storage element in a sequence of storage elements,
feeding a first DC signal to the first storage element,
feeding the second periodic signal, as a second AC signal, to a second storage element in the sequence of storage elements,
feeding a second DC signal to the second storage element, wherein at least one of a voltage of the first DC signal and a voltage of the second DC signal differs at two different points in time, and
during a plurality of periods of the first AC signal, keeping the first and second DC signals constant and detecting any current transmitted between the first storage element and the second storage element,
deriving the information from the determined currents.

27. The method according to claim 26, wherein the second periodic signal is a sine-shaped or saw-tooth shaped signal.

28. The method according to claim 26, wherein the second periodic signal is the first periodic signal delayed, or phase shifted by a predetermined portion, and wherein the step of deriving the information comprises basing the information also on the delay or phase shift.

29. The method according to claim 28, wherein a delay is identified at which at least substantially no current is generated, and
wherein the information relates to the delay.

30. The method according to claim 28, wherein the step of deriving the information comprises sequentially selecting a plurality of delays and basing the determination on the currents detected and the delays.

31. The method according to claim 28, wherein one or both of the first and second DC voltages are altered between adjacent points in time of the plurality of points in time.

32. The method according to claim 28, wherein the deriving step comprises deriving information relating to a voltage over time of the first periodic signal.
